(19) United States
(12) Patent Application Publication
(10) Pub. No.: US 2024/0389240 A1
(43) Pub. Date: Nov. 21, 2024

(54) MATERIALS FOR SEMICONDUCTOR PACKAGE MOUNT APPLICATIONS AND METHODS OF USING THE SAME

(71) Applicant: Taiwan Semiconductor Manufacturing Company Limited, Hsinchu (TW)

(72) Inventors: Chao-Wei Chiu, Hsinchu City (TW); Chih-Chiang Tsao, Taoyuan City (TW); Jen-Jui Yu, Taipei City (TW); Hsuan-Ting Kuo, Taichung City (TW); Hsiu-Jen Lin, Zhubei City (TW); Ching-Hua Hsieh, Hsinchu (TW)

(21) Appl. No.: 18/789,626

(22) Filed: Jul. 30, 2024

Related U.S. Application Data
(62) Division of application No. 18/304,500, filed on Apr. 21, 2023.
(60) Provisional application No. 63/409,873, filed on Sep. 26, 2022.

(51) Int. Cl. H05K 3/34; B23K 35/02; B23K 35/26; B23K 101/40; C22C 13/00; H01L 23/00; H01L 23/31; H01L 23/498; H01L 23/538; H01L 25/18; H01R 4/02; H01R 4/62; H05K 1/18; H10B 80/00

(52) U.S. Cl. CPC H05K 3/3463; B23K 35/0244; B23K 35/262; C22C 13/00; H01L 23/49816; H01L 23/49866; H01L 23/562; H01L 25/18; H01R 4/02; H01R 4/625; H05K 1/181; H05K 3/3436; H05K 3/3494; H10B 80/00; B23K 2101/40; H01L 23/3185; H01L 23/5385; H01L 24/16; H01L 24/32; H01L 24/73; H01L 2224/16227; H01L 2224/32225; H01L 2224/73204; H05K 2201/10378; H05K 2201/10734; H05K 2201/10992; H05K 2203/047; H05K 2203/0475

(57) ABSTRACT

An embodiment composite material for semiconductor package mount applications may include a first component including a tin-silver-copper alloy and a second component including a tin-bismuth alloy or a tin-indium alloy. The composite material may form a reflowed bonding material having a room temperature tensile strength in a range from 80 MPa to 100 MPa when subjected to a reflow process. The reflowed bonding material may include a weight fraction of bismuth that is in a range from approximately 4% to approximately 15%. The reflowed bonding material may an alloy that is solid solution strengthened by a presence of bismuth or indium that is dissolved within the reflowed bonding material or a solid solution phase that includes a minor component of bismuth dissolved within a major component of tin. In some embodiments, the reflowed bonding material may include intermetallic compounds formed as precipitates such as Ag₃Sn and/or Cu₆Sn₅.

### RELATED APPLICATIONS

This application is a divisional application of U.S. application Ser. No. 18/304,500, entitled “Improved Materials for Semiconductor Package Mount Applications and Methods of Using the Same,” filed on Apr. 21, 2023, which claims the benefit of priority to U.S. Provisional Application No. 63/409,873, entitled “Improved Materials for Semiconductor Package Mount Applications and Methods of Using the Same,” filed on Sep. 26, 2022, the entire contents of both of which are incorporated by reference herein for all purposes.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens, hundreds, or thousands of integrated circuits are typically manufactured on a single semiconductor wafer, and individual dies on the wafer are singulated by sawing between the integrated circuits along scribe lines. The individual dies are typically packaged separately, in multi-chip modules, or in other types of packaging, for example. However, there are many challenges related to fabricating and operating 3-dimensional devices such as mechanical issues related to thermal expansion mismatch between package components leading to warpage, cracking, delamination, etc.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is vertical cross-sectional exploded view of components of a semiconductor package during a package assembly and surface mounting process.

FIG. 1B is a vertical cross-sectional view illustrating an assembled semiconductor package mounted onto the surface of a support substrate.

FIG. 2A is a top view of a semiconductor package including a first reinforcement structure.

FIG. 2B is a vertical cross-sectional view of the semiconductor package along line BB′ in FIG. 2A.

FIG. 2C is a vertical cross-sectional view of an enlarged portion of the semiconductor package of FIG. 2B.

FIG. 3A is a vertical cross-sectional view of an intermediate structure that may be used to form a semiconductor package, according to various embodiments.

FIG. 3B is a vertical cross-sectional view of a further intermediate structure that may be used to form a semiconductor package, according to various embodiments.

FIG. 3C is a vertical cross-sectional view of a semiconductor package, according to various embodiments.

FIG. 4A is a vertical cross-sectional view of an intermediate structure including a composite material for semiconductor package mount applications, according to various embodiments.

FIG. 4B is a vertical cross-sectional view of a further intermediate structure including a composite material for semiconductor package mount applications, according to various embodiments.

FIG. 4C is a vertical cross-sectional view of a mounted structure in which the composite material of FIGS. 4A and 4B has been used to bond a package substrate to a support substrate, according to various embodiments.

FIG. 5 is the phase diagram for a tin-bismuth alloy.

FIG. 6 is a plot of bismuth concentration in a reflowed bonding material of the composite material for semiconductor package mount applications, according to various embodiments.

FIG. 7A is a vertical cross-sectional view of an intermediate structure that may be used to form a semiconductor package, according to various embodiments.

FIG. 7B is a vertical cross-sectional view of a further intermediate structure that may be used to form a semiconductor package, according to various embodiments.

FIG. 7C is a vertical cross-sectional view of a semiconductor package, according to various embodiments.

FIG. 8 is a flowchart illustrating operations of a method of bonding a first component of a semiconductor package to a second component of the semiconductor package using a composite material for semiconductor package mount applications.

### DETAILED DESCRIPTION

The following disclosure provides many different embodiments, or examples, for implementing various features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, this disclosure may repeat reference numerals and/or letters in the disclosed example embodiments. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Typically, in a semiconductor package, a number of semiconductor integrated circuit (IC) dies (i.e., “chips”) may be mounted onto a common substrate. The chips mounted on the common substrate may also be referred to as a “package substrate.” In some embodiments, electrical connections to the semiconductor package may be made by mounting the package substrate onto a support substrate containing electrical interconnects, such as a printed circuit board (PCB).

The various embodiments disclosed herein may provide a composite material for semiconductor package mount applications that may allow a first reflow process to be performed at a lower temperature than that of a second reflow process. In this regard, disclosed embodiments may include a composite material having a core structure (a first component) and a shell structure (a second component), such that the shell structure may have a lower liquidus point than that of the core structure. As such, a first reflow process used to attach the composite material to a first component may be performed at a lower temperature than a second reflow process used to attach the composite material to a second component to thereby bond the first and second components to one another. Thermal stresses and corresponding degradation and damage, caused by such thermal stresses, may be reduced by using a first reflow process that has a lower reflow temperature than a second reflow process. As a further advantage, the composite material, once having been subjected to the first reflow process and the second reflow process, may have a greater tensile strength than existing materials used for semiconductor package mount applications.

An embodiment composite material for semiconductor package mount applications may include a first component including a tin-silver-copper alloy and a second component including a tin-bismuth alloy or a tin-indium alloy. The composite material may form a reflowed bonding material having a room temperature tensile strength in a range from 80 MPa to 100 MPa when subjected to a reflow process. The reflowed bonding material may include a weight fraction of bismuth that is in a range from approximately 4% to approximately 15%. The reflowed bonding material may include an alloy that is solid solution strengthened by a presence of bismuth or indium that is dissolved within the reflowed bonding material or a solid solution phase that includes a minor component of bismuth dissolved within a major component of tin. In some embodiments, the reflowed bonding material may include intermetallic compounds formed as precipitates such as Ag₃Sn and/or Cu₆Sn₅.

A further reflowed bonding material for semiconductor package mount applications may include a tin-silver-copper-bismuth alloy or a tin-silver-copper-indium alloy having a room temperature tensile strength in a range from approximately 80 MPa to approximately 100 MPa. The reflowed bonding material may include a weight fraction of bismuth that is in a range from approximately 4% to approximately 15% that has a radially varying spatial distribution. In some embodiments, the reflowed bonding material may include intermetallic compounds formed as precipitates such one or more of Ag₃Sn and Cu₆Sn₅. In other embodiments, the reflowed bonding material may include an alloy that is solid solution strengthened by a presence of bismuth or indium that is dissolved within the reflowed bonding material. Alternatively, the reflowed bonding material may include a solid solution phase that includes a minor component of bismuth dissolved within a major component of tin.

An embodiment method of bonding a first component of a semiconductor package to a second component of the semiconductor package may include placing a composite material on a first bonding pad of the first component of the semiconductor package, where the composite material includes a core structure including a tin-silver-copper alloy and a shell structure including a tin-bismuth alloy or a tin-indium alloy; performing a first reflow process to melt the shell structure without melting the core structure, where the first reflow process bonds the composite material to the first bonding pad; aligning the second component of the semiconductor package with the first component of the semiconductor package such that the composite material is in contact with a second bonding pad of the second component; and performing a second reflow process to melt both the core structure and the shell structure to form a reflowed bonding material that bonds the first bonding pad and the second bonding pad.

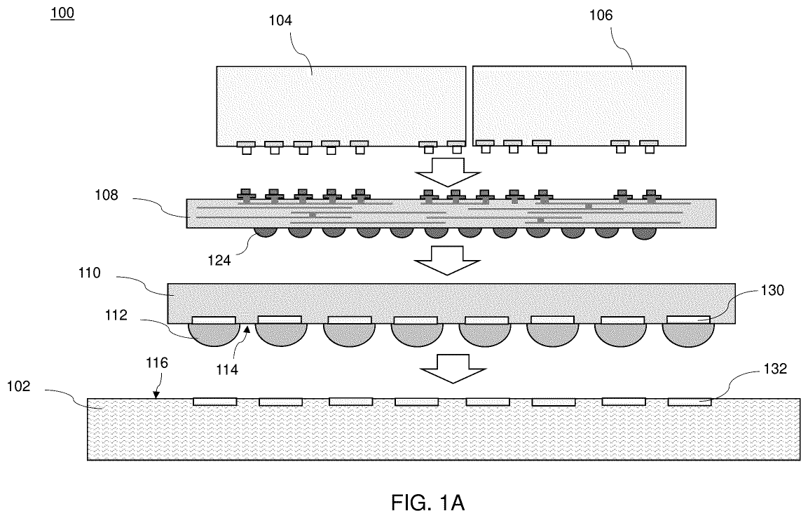

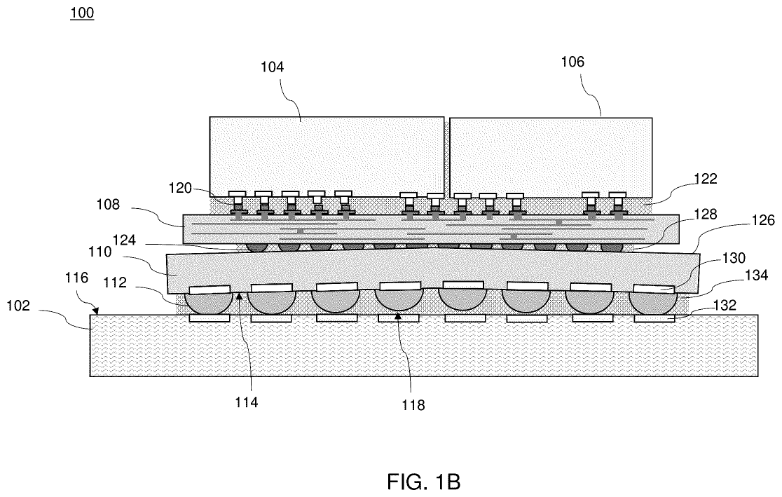

FIG. 1A is vertical cross-section exploded view of components of a semiconductor package 100 during a package assembly and surface mounting process. FIG. 1B is a vertical cross-section view illustrating the assembled semiconductor package 100 mounted onto the surface of a support substrate 102, such as a printed circuit board (PCB). The semiconductor package 100 in this example is a chip-on-wafer-on-substrate (CoWoS)® semiconductor package, although it will be understood that a similar assembly and mounting process may be utilized for other types of semiconductor packages, such as integrated fan-out (InFO) semiconductor packages, flip-chip semiconductor packages, etc.

Referring to FIGS. 1A and 1B, the semiconductor package 100 may include integrated circuit (IC) semiconductor dies, such as first semiconductor dies 104 and second semiconductor dies 106. During the package assembly process, the first semiconductor die 104 and the second semiconductor die 106 may be mounted on an interposer 108, and the interposer 108 containing the first semiconductor die 104 and the second semiconductor die 106 may be mounted onto a package substrate 110 to form a semiconductor package 100. The semiconductor package 100 may then be mounted to a support substrate 102, such as a printed circuit board (PCB), by mounting the package substrate 110 to the support substrate 102 using an array of solder balls 112 on the lower surface 114 of the package substrate 110.

A parameter that may ensure proper interconnection between the package substrate 110 and the support substrate 102 is the degree of co-planarity between the surfaces of the solder balls 112 that may be brought into contact with the mounting surface (i.e., the upper surface 116 of the support substrate 102 in FIG. 1A). A low amount of co-planarity between the solder balls 112 may result in instances of solder cold joints (i.e., insufficient melting of the solder material, resulting in a poor bond that is susceptible to cracking and separation) and/or solder bridging issues (i.e., solder material from one solder ball 112 contacting material from a neighboring solder ball 112, resulting in an unintended connection (i.e., electrical short)) during the reflow process.

Deformation of the package substrate 110, such as stress-induced warping of the package substrate 110, may be a contributor to low co-planarity of the solder balls 112 during surface mounting of the package substrate 110 onto a support substrate 102. FIG. 1B illustrates a package substrate 110 that includes a warpage deformation. The warp deformation of the package substrate 110 may result in variations of the distance between the lower surface 114 of the package substrate 110 and the upper surface 116 support substrate 102. Such deformation of the package substrate 110 may increase the risk of defective solder connections with the underlying support substrate 102. As shown in FIG. 1B, for example, a deformation of the package substrate 110 may cause at least some of the solder joints between the package substrate 110 and the support substrate 102 to fail completely, as indicated by the arrow 118 in FIG. 1B. In the exemplary embodiment shown in FIG. 1B, the deformation of the package substrate 110 may have a bow-shape or cup-shape such that a separation between the lower surface 114 of the package substrate 110 and the upper surface 116 of the support substrate 102 may be smallest at the periphery of the package substrate 110 and may increase towards the center of the package substrate 110.

Deformation of the package substrate 110 is not an uncommon occurrence, particularly in the case of semiconductor packages used in high-performance computing applications. These high-performance semiconductor packages 100 tend to be relatively large and may include a number of semiconductor dies (e.g., 104, 106) mounted to the package substrate 110. The thermal load generated by such semiconductor dies (e.g., 104, 106) and the differences in coefficients of thermal expansion (CTE) often results in warpage and other deformations of the package substrate 110 and other components of the semiconductor package 100. Such deformations may present challenges to effective solder mounting of these types of semiconductor package substrates 110 onto a support substrate 102.

According to various embodiments of this disclosure, a substrate for a semiconductor package 100 may include various reinforcing structures that may compensate for a deformation of the package substrate 110 so that the co-planarity of the solder balls 112 may be improved, thereby providing an improved solder connection between the package substrate 110 and the support substrate 102, as described in greater detail below.

In various embodiments, the first semiconductor dies 104 may be three-dimensional devices, such as three-dimensional integrated circuits (3DICs), System on Chip (SOC) or System on Integrated Circuit (SoIC) devices. A three-dimensional semiconductor device may be formed by placing chips over chips on a semiconductor wafer level. These three-dimensional devices may provide improved integration density and other advantages, such as faster speeds and higher bandwidths, due to a decreased length of interconnects between the stacked chips. In some embodiments, a first three-dimensional semiconductor device may also be referred to as a “first die stack.”

The second semiconductor dies 106 may be different from the first semiconductor dies 104 in terms of their structure, design and/or functionality. The one or more second semiconductor dies 106 may be three-dimensional semiconductor dies, which may also be referred to as “second die stacks.” In some embodiments, the one or more second semiconductor dies 106 may include a memory device, such as a high bandwidth memory (HBM) device. In the example shown in FIGS. 1A and 1B, the semiconductor package 100 may include a first semiconductor die that may be configured as a SOC die stack and a second semiconductor die 106 that may be configured as a HBM die stack, although it will be understood that the semiconductor package 100 may include greater or fewer numbers of semiconductor dies.

Referring again to FIG. 1B, the first semiconductor dies 104 and second semiconductor dies 106 may be mounted on an interposer 108. In some embodiments, the interposer 108 may be an organic interposer including a polymer dielectric material (e.g., a polyimide material) having a plurality of metal interconnect structures extending therethrough. In other embodiments, the interposer 108 may be a semiconductor interposer, such as a silicon interposer, having a plurality of interconnect structures (e.g., through-silicon vias) extending therethrough. Other suitable configurations for the interposer 108 are within the contemplated scope of the disclosure. The interposer 108 may include a plurality of conductive bonding pads on upper and lower surfaces of the interposer 108 and a plurality of conductive interconnects extending through the interposer 108 between the upper and lower bonding pads of the interposer 108. The conductive interconnects may distribute and route electrical signals between the first semiconductor dies 104, the second semiconductor dies 106, and the underlying package substrate 110. Thus, the interposer 108 may also be referred to as a redistribution layer (RDL).

A plurality of metal bumps 120, such as microbumps, may electrically connect conductive bonding pads on the bottom surfaces of the first semiconductor dies 104 and second semiconductor dies 106 to the conductive bonding pads on the upper surface of the interposer 108. In one non-limiting embodiment, metal bumps 120 in the form of microbumps may include a plurality of first metal stacks, such as a plurality of Cu—Ni—Cu stacks, located on the bottom surfaces of the first semiconductor dies 104 and second semiconductor dies 106, and a plurality of second metal stacks (e.g., Cu—Ni—Cu stacks) located on the upper surface of the interposer 108. A solder material, such as tin (Sn), may be located between respective first and second metal stacks to electrically connect the first semiconductor dies 104 and the second semiconductor dies 106 to the interposer 108. Other suitable materials for the metal bumps 120 are within the contemplated scope of disclosure.

After the first semiconductor dies 104 and second semiconductor dies 106 are mounted to the interposer 108, a first underfill material portion 122 may optionally be provided in the spaces surrounding the metal bumps 120 and between the bottom surfaces of the first semiconductor dies 104, the second semiconductor dies 106, and the upper surface of the interposer 108 as shown in FIG. 1B. The first underfill material portion 122 may also be provided in the spaces laterally separating adjacent first semiconductor dies 104 and second semiconductor dies 106 of the semiconductor package 100. In various embodiments, the first underfill material portion 122 may be include of an epoxy-based material, which may include a composite of resin and filler materials.

Referring again to FIG. 1B, the interposer 108 may be mounted on the package substrate 110 that may provide mechanical support for the interposer 108 and the first semiconductor dies 104 and second semiconductor dies 106 that are mounted on the interposer 108. The package substrate 110 may include a suitable material, such as an organic material (e.g., a polymer and/or thermoplastic material), a semiconductor material (e.g., a semiconductor wafer, such as a silicon wafer), a ceramic material, a glass material, combinations thereof, etc. Other suitable substrate materials are within the contemplated scope of present disclosure. In various embodiments, the package substrate 110 may include a plurality of conductive bonding pads (not shown) in an upper surface 126 of the package substrate 110. A plurality of metal bumps 124, such as C4 solder bumps, may electrically connect conductive bonding pads (not shown) on the bottom surface of the interposer 108 to the conductive bonding pads on the upper surface 126 of the package substrate 110. In various embodiments, the metal bumps 124 may include a suitable solder material, such as tin (Sn), although other suitable solder materials are within the contemplated scope of disclosure.

A second underfill material portion 128 may be provided in the spaces surrounding the metal bumps 124 and between the bottom surface of the interposer 108 and the upper surface 126 of the package substrate 110 as illustrated, for example, in FIG. 1B. In various embodiments, the second underfill material portion 128 may include an epoxy-based material, which may include a composite of resin and filler materials. In some embodiments, a lid or cover (not shown in FIGS. 1A and 1B) may be mounted to the package substrate 110 and may provide an enclosure around the upper and side surfaces of the first semiconductor dies 104 and second semiconductor dies 106.

As described above, the package substrate 110 may be mounted to the support substrate 102, such as a printed circuit board (PCB). Other suitable support substrates 102 are within the contemplated scope of disclosure. The package substrate 110 may include a plurality of conductive bonding pads 130 in a lower surface 114 of the package substrate 110. A plurality of conductive interconnects (not shown) may extend through the package substrate 110 between conductive bonding pads on the upper surface 126 and lower surface 114 of the package substrate 110. The plurality of solder balls (or bump structures) 112 may electrically connect the conductive bonding pads 130 on the lower surface 114 of the package substrate 110 to a plurality of conductive bonding pads 132 on the upper surface 116 of the support substrate 102.

The conductive bonding pads 130 of the package substrate 110 and conductive bonding pads 132 of the support substrate 102 may be formed of a suitable conductive material, such as copper. Other suitable conductive materials are within the contemplated scope of disclosure. The plurality of solder balls 112 on the lower surface 114 of the package substrate 110 may form an array of solder balls 112, such as a ball grid array (BGA) that may include an array pattern that corresponds to an array pattern of the conductive bonding pads 132 on the upper surface 116 of the support substrate 102. In one non-limiting example, the array of solder balls 112 may include a grid pattern and may have a pitch (i.e., distance between the center of each solder ball 112 and the center of each adjacent solder ball 112). In an example embodiment, the pitch may be between about 0.8 and 1.0 mm, although larger and smaller pitches may be used.

The solder balls 112 may include any suitable solder material, such as tin, lead, silver, indium, zinc, nickel, bismuth, antimony, cobalt, copper, germanium, alloys thereof, combinations thereof, or the like. For example, the solder balls 112 may include a composite structure having a tin-silver-copper alloy surrounded by a tin-bismuth alloy or a tin-indium alloy. Other suitable materials for the solder balls 112 are within the contemplated scope of disclosure.

In some embodiments, the lower surface 114 of the package substrate 110 may include a coating of solder resist (SR) material (not shown), which may also be referred to as a “solder mask”. A SR material coating may provide a protective coating for the package substrate 110 and any underlying circuit patterns formed on or within the package substrate 110. An SR material coating may also inhibit solder material from adhering to the lower surface 114 of the package substrate 110 during a reflow process. In embodiments in which the lower surface 114 of the package substrate 110 includes an SR coating, the SR material coating may include a plurality of openings through which the conductive bonding pads 130 may be exposed.

In various embodiments, each of the conductive bonding pads 130 in different regions of the package substrate 110 may have the same size and shape. In the embodiment shown in FIGS. 1A and 1B, the surfaces of the conductive bonding pads 130 may be substantially co-planar with the lower surface 114 of the package substrate 110, which in some embodiments may include a solder resist (SR) coating.

Alternatively, the surfaces of the conductive bonding pads 130 may be recessed relative to the lower surface 114 of the package substrate 110. In some embodiments, the surfaces of the conductive bonding pads 130 may be raised relative to the lower surface 114 of the package substrate 110.

Referring again to FIGS. 1A and 1B, solder balls 112 may be provided over the respective conductive bonding pads 130. In one non-limiting example, the conductive bonding pads 130 may have a width dimension that is between about 500 μm and about 550 μm (e.g., ˜530 μm), and the solder balls 112 may have an outer diameter that may be between about 600 μm and about 650 μm (e.g., ˜630 μm), although greater and lesser dimensions for the solder balls 112 and/or the conductive bonding pads 130 are within the contemplated scope of disclosure.

A first solder reflow process may include subjecting the package substrate 110 to an elevated temperature (e.g., between 235° C. and 245° C.) in order to melt the solder balls 112 and cause the solder balls 112 to adhere to the conductive bonding pads 130. Following the first reflow process, the package substrate 110 may be cooled causing the solder balls 112 to re-solidify. Following the first solder reflow process, the solder balls 112 may adhere to the conductive bonding pads 130. Each solder ball 112 may extend from the lower surface 114 of the package substrate 110 by a vertical height that may be less than the outer diameter of the solder ball 112 prior to the first reflow process. For example, where the outer diameter of the solder ball 112 is between about 600 μm and about 650 μm (e.g., ˜630 μm), the vertical height of the solder ball 112 following the first reflow process may be between about 500 μm and about 550 μm (e.g., ˜520 μm).

In various embodiments, the process of mounting the package substrate 110 onto the support substrate 102 as shown in FIG. 1B, may include aligning the package substrate 110 over the support substrate 102, such that the solder balls 112 contacting the conductive bonding pads 130 of the package substrate 110 may be located over corresponding bonding pads (e.g., conductive bonding pads 132) on the support substrate 102. A second solder reflow process may then be performed. The second solder reflow process may include subjecting the package substrate 110 to an elevated temperature (e.g., at about 250° C.) to thereby melt the solder balls 112 and cause the solder balls 112 to adhere to the corresponding conductive bonding pads 132 on the support substrate 102. Surface tension may cause the semi-liquid solder to maintain the package substrate 110 in alignment with the support substrate 102 while the solder material cools and solidifies. Upon solidification of the solder balls 112, the package substrate 110 may sit above the upper surface 116 of the support substrate 102 by a stand-off height that may be between about 0.4 mm to about 0.5 mm, although greater or lesser stand-of heights are within the contemplated scope of disclosure.

Following the mounting of the package substrate 110 to the support substrate 102, a third underfill material portion 134 may be provided in the spaces surrounding the solder balls 112 and between the lower surface 114 of the package substrate 110 and the upper surface 116 of the support substrate 102, as is shown in FIG. 1B. In various embodiments, the third underfill material portion 134 may include an epoxy-based material, which may include a composite of resin and filler materials.

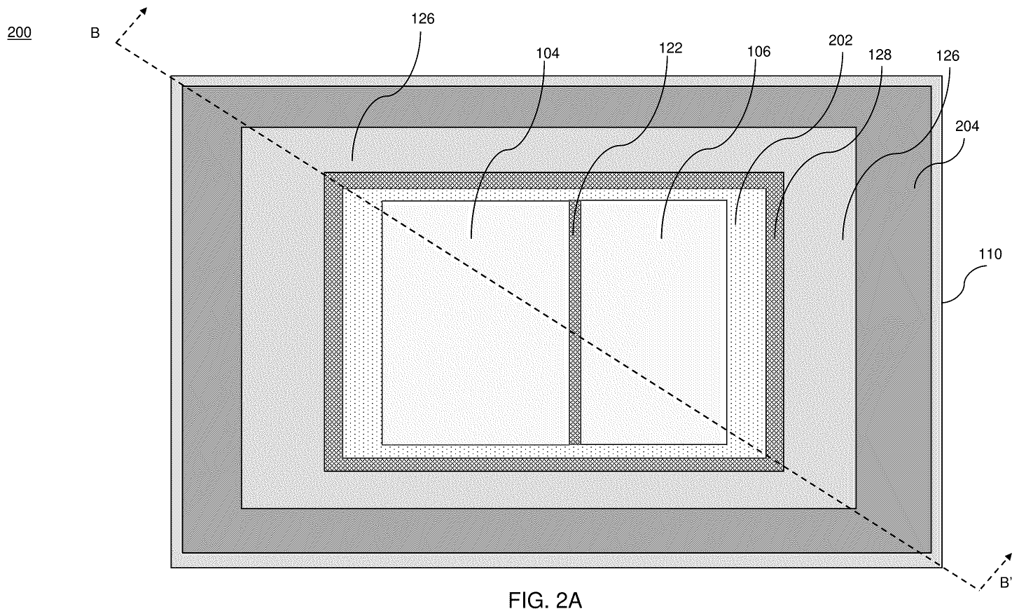

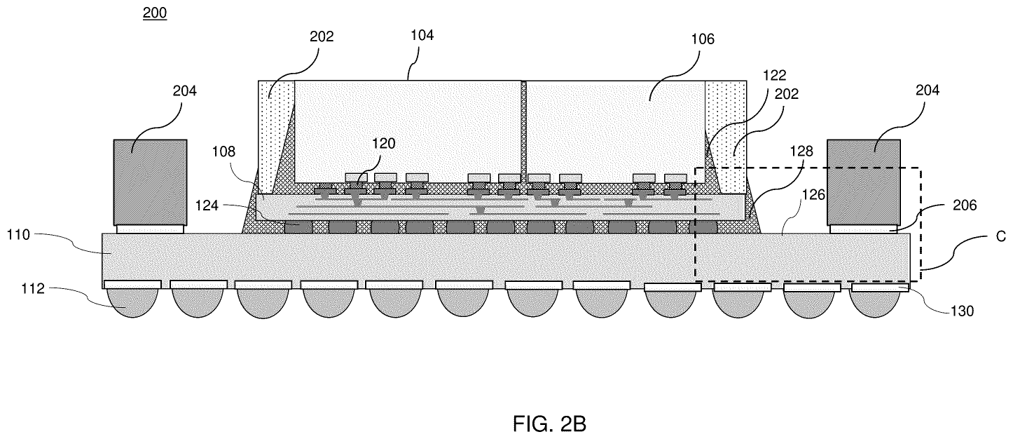

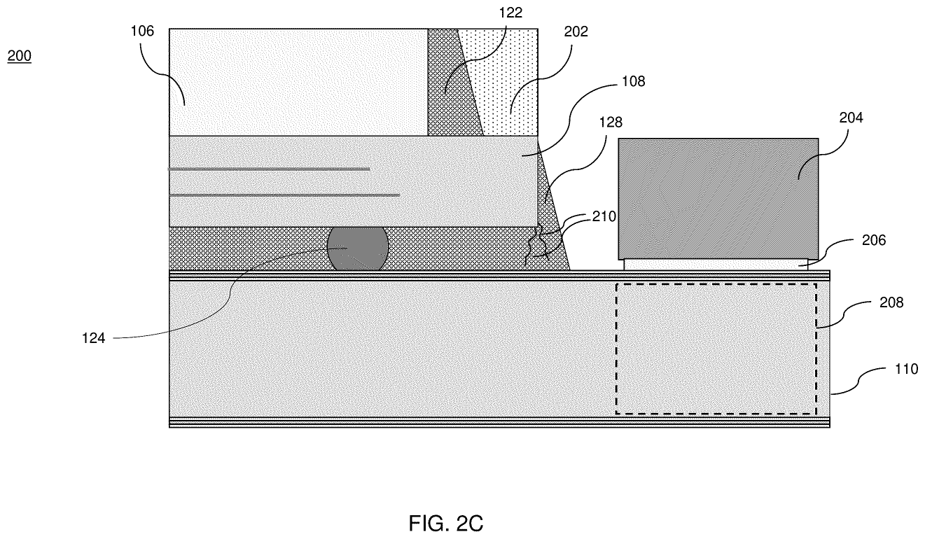

FIG. 2A is a top view of a semiconductor package 200 including a first reinforcement structure 204 (such as a stiffener ring), which may be provided to reduce or eliminate the warpage distortion of the package substrate 110 shown in FIG. 1B. The dashed line labeled B-B′ indicates the cross-sectional view of the semiconductor package 200 shown in FIG. 2B, as described in greater detail, below. The semiconductor package 200 may be similar to the semiconductor package 100 of FIGS. 1A and 1B. In this regard, the semiconductor package 200 may include a first semiconductor die 104 and a second semiconductor die 106 mounted to an interposer 108 (e.g., see FIG. 2B). The interposer 108 may be mounted to a package substrate 110, as described above with reference to FIGS. 1A and 1B. The semiconductor package 200 may include a first underfill material portion 122 provided in the spaces laterally separating adjacent first semiconductor die 104 and second semiconductor die 106 of the semiconductor package 200. The semiconductor package 200 may also include a second underfill material portion 128 may be provided in the spaces surrounding the metal bumps 124 and between the bottom surface of the interposer 108 and the upper surface 126 of the package substrate 110 as illustrated, for example, in FIG. 2B.

The semiconductor package 200 may further include an epoxy molding compound (EMC) that may be applied to gaps formed between the interposer 108, the first semiconductor die 104, and the second semiconductor die 106, to thereby form a multi-die EMC frame 202. The EMC material may include an epoxy-containing compound that may be hardened (i.e., cured) to provide a dielectric material portion having sufficient stiffness and mechanical strength. The EMC material may include epoxy resin, hardener, silica (as a filler material), and other additives. The EMC material may be provided in a liquid form or in a solid form depending on the viscosity and flowability.

Liquid EMC may provide better handling, good flowability, fewer voids, better fill, and fewer flow marks. Solid EMC may provide less cure shrinkage, better stand-off, and less die drift. A high filler content (such as 85% in weight) within an EMC material may shorten the time in mold, lower the mold shrinkage, and reduce the mold warpage. A uniform filler size distribution in the EMC material may reduce flow marks and may enhance flowability. The curing temperature of the EMC material may be in a range from 125° C. to 150° C. The multi-die EMC frame 202 may be cured at a curing temperature to form an EMC matrix that laterally encloses each of the first semiconductor die 104 and the second semiconductor die 106. Excess portions of the multi-die EMC frame 202 may be removed from above the horizontal plane including the top surfaces of the semiconductor dies (104, 106) by a planarization process, such as CMP.

FIG. 2B is a cross-sectional view of the semiconductor package 200 of FIG. 2A. The first reinforcement structure 204 may be attached to the package substrate 110 with an adhesive 206 and may be formed of a metal, an insulator, a semiconductor, a ceramic, etc. For example, in one embodiment, the first reinforcement structure 204 may include copper at an atomic percentage greater than 80%, such as greater than 90% and/or greater than 95% although greater or lesser percentages may be used. As shown in FIG. 2A, the first reinforcement structure 204 may be configured as a ring located around a periphery of the package substrate 110. As such, the first reinforcement structure 204 may form a single structure. Alternatively, the first reinforcement structure 204 may include several disconnected portions (not shown). Further, the first reinforcement structure 204 need not be located near the periphery of the package substrate 110. Rather, the first reinforcement structure 204 may located on the package substrate 110 in any region that may be subject to mechanical distortions such as warping.

The first reinforcement structure 204 may provide increased mechanical support to the package substrate 110 to thereby reduce or eliminate mechanical distortions such as the warping of the package substrate 110 described above and illustrated, for example, in FIG. 1B. The first reinforcement structure 204 may therefore be chosen to have a mechanical strength (e.g., bulk modulus) that is greater than that of the package substrate 110. As discussed above, the package substrate 110 may include an organic material (e.g., a polymer and/or thermoplastic material), a semiconductor material (e.g., a semiconductor wafer, such as a silicon wafer), a ceramic material, a glass material, combinations thereof, etc. As such, the choice of material for the first reinforcement structure 204 may be chosen based on the mechanical properties of the package substrate 110. As shown in FIG. 2B, for example, the presence of the first reinforcement structure 204 may reduce or eliminate the warpage distortion of the package substrate 110 shown in FIG. 1B. However, the presence of the first reinforcement structure 204 may give rise to other mechanical issues as described in greater detail with reference to FIG. 2C, below.

FIG. 2C is a cross-sectional view of an enlarged portion of the semiconductor package of FIG. 2B. The region shown in FIG. 2C is illustrated in the dashed rectangle labeled C in FIG. 2B. For certain material compositions, there may be a mismatch in thermal expansion coefficients of components of the semiconductor package 200 relative to a thermal expansion coefficient of the first reinforcement structure 204. As such, thermal expansion stresses may develop during thermal cycling. Such thermal stresses may lead to mechanical degradation of the semiconductor package 200. For example, as shown in FIG. 2C, cracks 210 may develop in the second underfill material portion 128. Further, the second underfill material portion 128 may become delaminated (not shown) from the package substrate 110 and/or from the interposer 108. In various disclosed embodiments, a second reinforcement structure may be provided to compensate the thermal stresses developed between components of the semiconductor package 200 the first reinforcement structure 204. For example, a second reinforcement structure may be formed within the package substrate 110 (e.g., within region 208), in various embodiments.

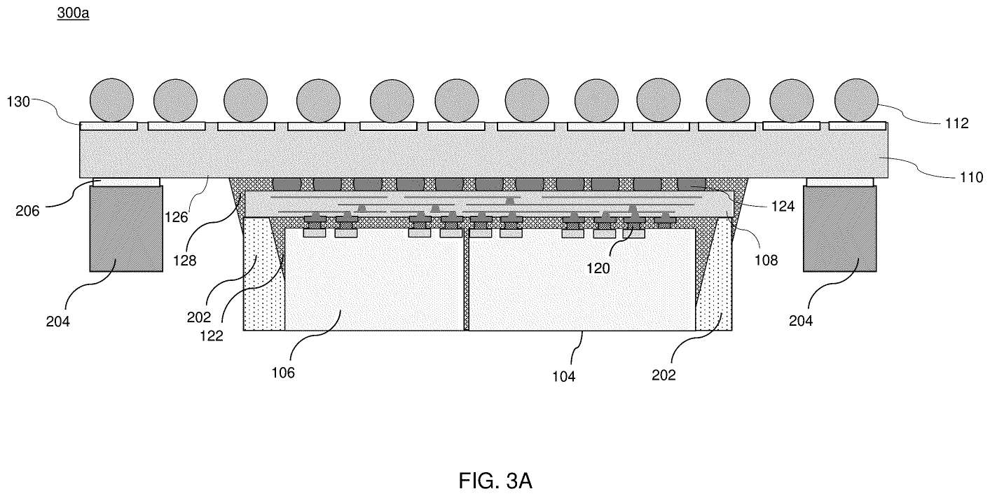

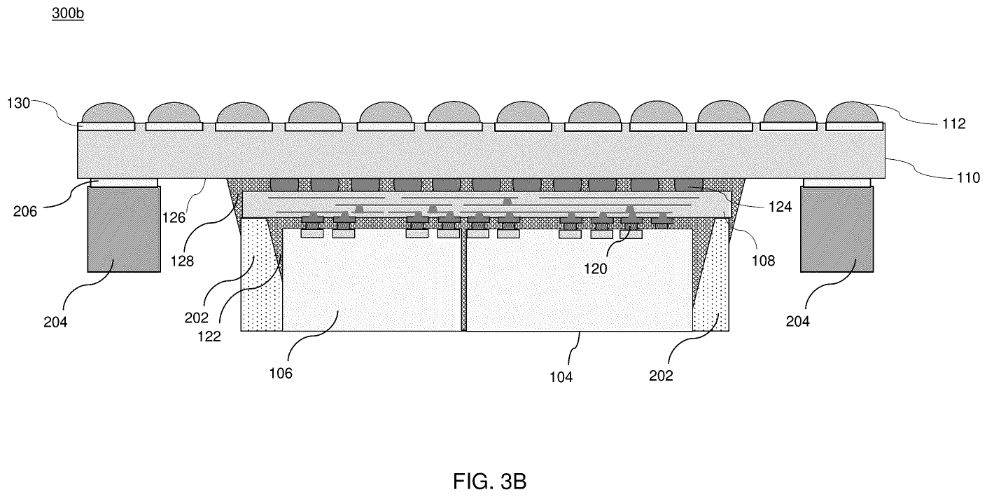

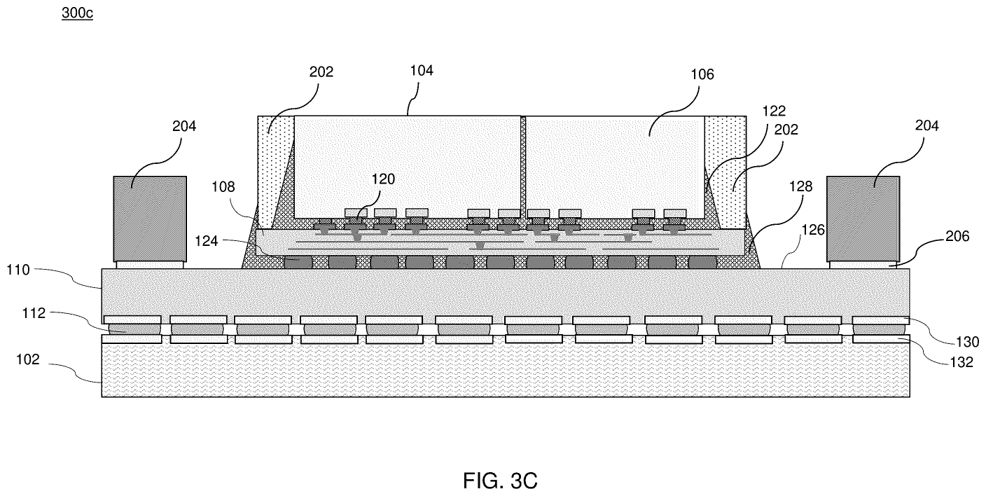

FIG. 3A is a vertical cross-sectional view of an intermediate structure 300a that may be used to form a semiconductor package, and FIG. 3B is a vertical cross-sectional view of a further intermediate structure 300b that may be used to form the semiconductor package, according to various embodiments. The intermediate structure 300a illustrates placement of solder balls 112 on bonding pads 130 of the package substrate 110 prior to a first reflow process and the intermediate structure 300b shows a configuration of the structure after the first reflow process.

The intermediate structure 300a and the intermediate structure 300b may include components similar to those of the semiconductor package 200, described above with reference to FIGS. 2A to 2C. In this regard, the intermediate structure 300a and the intermediate structure 300b may each include a first semiconductor die 104 and a second semiconductor die 106 that may be mounted to an interposer 108. A plurality of metal bumps 120, such as microbumps, may electrically connect conductive bonding pads on the bottom surfaces of the first semiconductor dies 104 and second semiconductor dies 106 to the conductive bonding pads on the upper surface of the interposer 108. The interposer 108 may further be mounted to the package substrate 110. A plurality of metal bumps 124, such as C4 solder bumps, may electrically connect conductive bonding pads (not shown) on the bottom surface of the interposer 108 to the conductive bonding pads on the upper surface 126 of the package substrate 110.

A first underfill material portion 122 may be formed between the first semiconductor die 104 and the interposer 108 and between the second semiconductor die 106 and the interposer 108, and a multi-die EMC frame 202 may be formed around the first semiconductor die 104 and the second semiconductor die 106. A second underfill material portion 128 may be formed between the interposer 108 and the package substrate 110. The intermediate structure 300a and the intermediate structure 300b may each further include a first reinforcement structure 204. The first reinforcement structure 204 may be attached to the package substrate 110 with an adhesive 206 and may be formed of a metal, an insulator, a semiconductor, a ceramic, etc.

A plurality of solder balls 112 may be placed over the conductive bonding pads 130 of the package substrate 110 prior to performing a first reflow process. As described above, a first reflow process may be performed to melt the solder balls 112 and cause the solder balls 112 to adhere to the conductive bonding pads 130 as shown, for example, in FIG. 3B. Following the first reflow process, the package substrate 110 may be cooled causing the solder balls 112 to re-solidify and to adhere to the conductive bonding pads 130, as shown in FIG. 3B.

As described above, the solder balls 112 may include any suitable solder material, such as tin, lead, silver, indium, zinc, nickel, bismuth, antimony, cobalt, copper, germanium, alloys thereof, combinations thereof, or the like. For example, the solder balls 112 may include a composite structure having a tin-silver-copper alloy surrounded by a tin-bismuth alloy or a tin-indium alloy. Other suitable materials for the solder balls 112 are within the contemplated scope of disclosure.

For a given composition of an alloy, the liquidous point (or liquidus temperature) is the temperature above which the alloy is in a uniform liquid phase (i.e., with no solid component). Similarly, for a given composition of an alloy, the solidus point (or solidus temperature) is the temperature below which the alloy is completely solid. For alloys in which the liquidous temperature and the solidus temperature do not coincide, the alloy may exist as a mixture of a liquid component and a solid component for temperatures above the solidus temperature and below the liquidus temperature. For certain materials, there is no distinction between the solidus temperature and the liquidus temperature, which may be called a melting/freezing temperature.

FIG. 3C is a vertical cross-sectional view of a semiconductor package 300c, according to various embodiments. The semiconductor package 300c may be formed by bonding the intermediate structure 300b of FIG. 3B to a support substrate 102. In this regard, the intermediate structure 300b of FIG. 3B may be aligned relative to the support substrate 102 such that the conductive bonding pads 130 of the package substrate 110 may be located over corresponding bonding pads 132 on the support substrate 102. A second solder reflow process may then be performed. To properly bond the solder balls 112 to the conductive bonding pads 132 of the support substrate 102 the second reflow process may be performed at a temperature that is sufficient to re-melt the solder balls. As such, the second reflow process may be performed a temperature in a range from approximately 235° C. to approximately 245° C.

The first reflow process and second reflow process may subject the structures (e.g., 300a, 300b) of FIGS. 3B and 3C to thermal stresses due to the differences in thermal expansion coefficients of the various components of the semiconductor package 300c. To reduce such effects, various disclosed embodiments provide composite materials for semiconductor package mount applications that may allow the first reflow process to be performed a lower temperature than that of the second reflow process. Further, such materials may exhibit increased tensile strength relative to the above-described materials that may be used for solder balls 112.

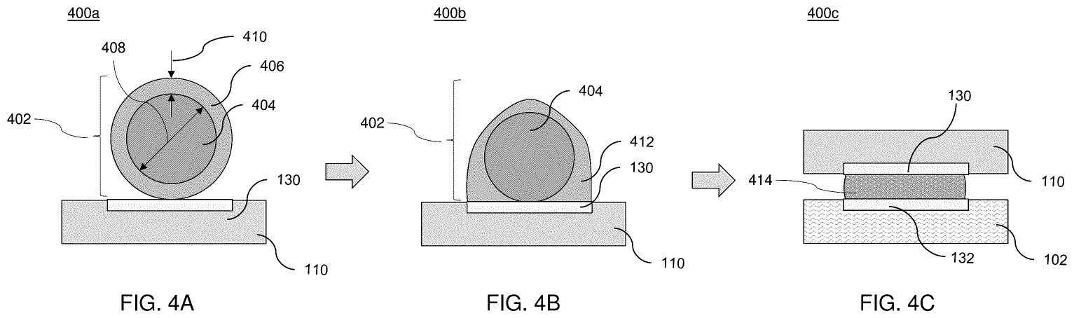

FIG. 4A is a vertical cross-sectional view of an intermediate structure 400a including a composite material 402 for semiconductor package mount applications, according to various embodiments. The intermediate structure 400a may further include a portion of the package substrate 110 and one of the conductive bonding pads 130 of the package substrate 110. As shown, the composite material 402 may include a core structure 404 and a shell structure 406. The core structure 404 may have an approximately spherical shape with a diameter 408 that is in a range from approximately 100 microns to approximately 600 microns, and the shell structure 406 may have a thickness 410 that is that is in a range from approximately 15 microns to approximately 40 microns. The core structure 404 may include a first material having a first liquidus point and the shell structure 406 may include a second material having a second liquidus point. The first material and the second material may be chosen such that the second liquidus point may be lower than the first liquidus point.

In one embodiment, the first material may include a tin-silver-copper alloy having a composition given by SnₓAg_{y}Cu_{z}, wherein x is a first weight fraction that has a value in a range from approximately 0.952 to approximately 0.965, y is a second weight fraction that has a value in a range from approximately 0.03 to approximately 0.04, and z is a third weight fraction that has a value in a range from approximately 0.005 to approximately 0.008. For such materials, the first liquidus point may be in an a range from approximately 210° C. to approximately 230° C. In certain embodiments, the first material may include a composition that is approximately one of Sn_{0.955}Ag_{0.04}Cu_{0.005}, Sn_{0.965}Ag_{0.030}Cu_{0.005}, or Sn_{0.985}Sn_{0.01}Cu_{0.005}. For some of these materials, the first liquidus point may be approximately 221° C. The above-described compositions are provided as examples, but are not intended to be limiting. Other embodiments may include various other compositions.

The second material may include a tin-bismuth alloy including a composition SnₓBi_{y}, where x is a first weight fraction having a value in a range from 0.42 to approximately 0.6 and y is as second weight fraction having a value in a range from approximately 0.4 to approximately 0.58. In other embodiments, the second material may include tin-indium alloy including a composition SnₓIn_{y}, where x is a first weight fraction having a value in a range from approximately 0.75 to approximately 0.85 and y is a second weight fraction having a value in a range from approximately 0.15 to approximately 0.25. For such materials, the second liquidus point may be in a range from approximately 130° C. to approximately 150° C. In certain embodiments, the first material may include a composition that is approximately one of Sn_{0.42}Bi_{0.58} or Sn_{0.8}In_{0.2}. For some of these materials, the second liquidus point may be approximately 141° C. The above-described compositions are provided as examples, but are not intended to be limiting. Other embodiments may include various other compositions.

FIG. 4B is a vertical cross-sectional view of a further intermediate structure 400b including the composite material 402 for semiconductor package mount applications, according to various embodiments. The intermediate structure 400b may be formed from the intermediate structure 400a of FIG. 4A by performing a first reflow process. Due to the lower liquidus point of the shell structure 406 (e.g., see FIG. 4A), the first reflow process may be performed at a temperature that is sufficient to melt the second material of the shell structure 406 without melting the first material of the core structure 404. In this regard, the first reflow process may be performed at a temperature that is in a first range from approximately 170° C. to approximately 180° C. As described above, the second material may have a liquidus point is in a range from approximately 130° C. to approximately 150° C., while the first material may have a liquidus point that is in an a range from approximately 210° C. to approximately 230° C. As such, the shell structure 406 may melt to form a reflowed second material 412 while leaving the first material of the core structure 404 un-melted. Upon cooling, the reflowed second material 412 may re-solidify and may thereby adhere to the conductive bonding pads 130.

FIG. 4C is a vertical cross-sectional view of a mounted structure 400c in which the composite material 402 of FIGS. 4A and 4B has been used to bond the package substrate 110 to a support substrate 102, according to various embodiments. In this regard, the package substrate 110 of FIG. 4B may be aligned over the support substrate such that the composite material 402 may be placed in contact with a conductive bonding pad 132 of the support substrate 102. In this way, the reflowed second material 412 of the composite material 402 (e.g., see FIG. 4B) may be placed in contact with the conductive bonding pad 132 of the support substrate 102. A second reflow process may then be performed to melt both the first material of the core structure 404 and the reflowed second material 412. To melt both the first material of the core structure 404 and the reflowed second material 412, the second reflow process may be performed at a temperature that is greater than the liquidus point of the reflowed second material 412 (e.g., greater than approximately 150° C.) and greater than the liquidus point of the first material (e.g., greater than approximately 230° C.). In this regard, the second reflow process may be performed at a temperature that is in a second range from approximately 235° C. to approximately 245° C.

During the second reflow process, the first material and the second material may mix and thereby form a reflowed bonding material 414 (e.g., see FIG. 4C) that may become adhered to both the conductive bonding pad 132 on the support substrate 102 and the conductive bonding pad 130 of the package substrate 110. Surface tension may cause the semi-liquid reflowed bonding material 414 to maintain the package substrate 110 in alignment with the support substrate 102 while the reflowed bonding material 414 cools and solidifies. Upon solidification, the conductive bonding pad 130 of the package substrate 110 may become mechanically and electrically bonded to the conductive bonding pad 132 of the support substrate 102.

Upon performing the second reflow process, the reflowed bonding material 414 may form an alloy of the first material and second material. The reflowed bonding material 414 may include a tin-silver-copper-bismuth alloy or a tin-silver-copper-indium alloy having a non-uniform spatial distribution of bismuth. For example, the bismuth or indium may have a non-uniform spatial distribution, which in some embodiments, may have a radially varying spatial distribution. In this regard, in some embodiments the bismuth or indium may have a greater concentration near a surface of the reflowed bonding material relative to a concentration in an interior of the reflowed bonding material. In other embodiments, the reflowed bonding material may include a tin-bismuth eutectic phase having a first concentration of the tin-bismuth eutectic phase that is located near a surface of the reflowed bonding material is greater than a second concentration of the tin-bismuth eutectic phase that is located in an interior of the reflowed bonding material.

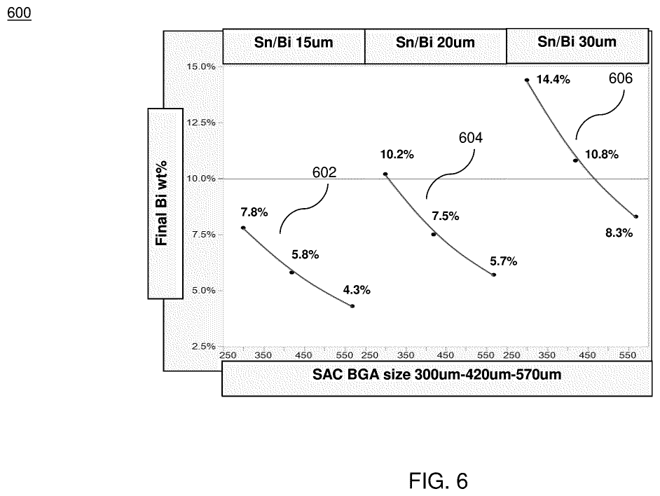

As such, the reflowed bonding material 414 may have material properties that may be distinct from those of the first material of the core structure 404 (e.g., see FIGS. 4A and 4B), the second material of the shell structure 406 (e.g., see FIG. 4A), and of the reflowed second material 412 (e.g., se FIG. 4B). For example, in some embodiments, the reflowed bonding material 414 may have a tensile strength in a range from approximately 80 MPa to approximately 100 MPa. In contrast, the first material of the core structure 404 may have a tensile strength that is approximately 49 MPa, while the second material of the shell structure 406 may have a tensile strength that is approximately 55 MPa. As described in greater detail below, the reflowed bonding material 414 may have a composition including tin, silver, copper, and bismuth. The concentration of bismuth may have weight fraction that is in a range from approximately 4% to approximately 15% (e.g., see FIG. 6). Depending on the composition of the various components, the reflowed bonding material 414 may be a solid solution or may be a multi-component solid having precipitates of various compositions.

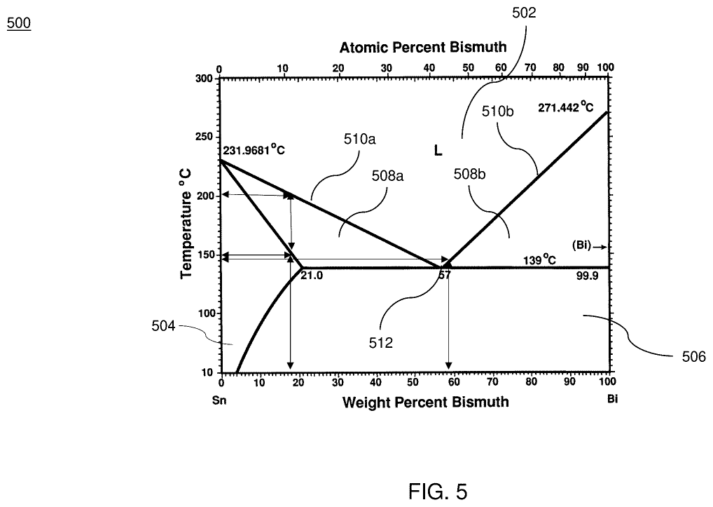

FIG. 5 is the phase diagram 500 for a tin-bismuth alloy. A composition of the first material of the shell structure 406 may be chosen based on the phase diagram 500. As shown, the phase diagram 500 may include a liquid region 502, a first solid region 504, and a second solid region 506. The phase diagram 500 may further include a first mixed region 508a, and a second mixed region 508b. The first mixed region 508a includes a solid/liquid mixture and is separated from the liquid region 502 by a first portion 510a of a liquidus line. The second mixed region 508b includes a further solid/liquid mixture and is separated from the liquid region 502 by a second portion 510b of the liquidous line. The first solid region 504 is a solid solution phase that includes a minor component of bismuth dissolved within a major component of tin. The first mixed region 508a includes a mixture of liquid and precipitates of the solid solution phase. The second mixed region 508b includes a mixture of liquid and precipitates of bismuth. The second solid region 506 includes a multi-component solid having precipitates of the solid solution phase and precipitates of bismuth.

The eutectic point 512 corresponds to a composition having the lowest temperature at which the alloy may melt. As shown, the eutectic point 512 corresponds to composition SnₓBi_{y} where x is approximately 0.4 (i.e., 40% tin) and y is approximately 0.57 (i.e., approximately 57% bismuth). The eutectic temperature is approximately 138° C. Thus, choosing the composition to be near the eutectic point 512 results in a first material of the shell structure 406 having the lowest possible liquidus/melting temperature. For example, a composition that is approximately equal to Sn_{0.42}Bi_{0.58} has a liquidus point that is approximately 141° C., as shown in FIG. 5. In contrast, a composition that is approximately equal to Sn_{0.82}Bi_{0.18}, for example, (see FIG. 5) has only begins to melt at a temperature of approximately 150° C. and is not fully melted until a temperature over 200° C. (i.e., the liquidus point is over 200° C.), as shown in FIG. 5. Thus, in various embodiments, it may be advantageous to choose the composition of the second material for the shell structure 406 to be close to the eutectic point (e.g., having a composition given by Sn_{0.42}Bi_{0.58}). The above-described compositions are provided as examples, but are not intended to be limiting. Other embodiments may include various other compositions.

FIG. 6 is a plot 600 of bismuth concentration in the reflowed bonding material 414 (e.g., see FIG. 4C), according to various embodiments. As described above, in some embodiments, the reflowed bonding material 414 may have a tensile strength in a range from approximately 80 MPa to approximately 100 MPa. In contrast, the first material of the core structure 404 may have a tensile strength that is approximately 49 MPa, while the second material of the shell structure 406 may have a tensile strength that is approximately 55 MPa. Thus, the increased tensile strength of the reflowed bonding material 414 may be due to the concentration of bismuth in the resulting alloy. The concentration of bismuth in the reflowed bonding material 414 may be controlled based on the compositions of the core structure 404, the composition of the shell structure 406, and the relative sizes of the core structure 404 and the shell structure. The resulting reflowed bonding material 414 (e.g., see FIG. 4C) may be an alloy that is solid solution strengthened by a presence of bismuth or indium that is dissolved within the reflowed bonding material. In other embodiments, the reflowed bonding material 414 may include intermetallic compounds formed as precipitates such as Ag₃Sn and/or Cu₆Sn₅.

FIG. 6 includes a first curve 602, a second curve 604, and a third curve 606. Each of the first curve 602, the second curve 604, and the third curve 606 correspond to a shell structure 406 having a composition approximately equal to Sn_{0.42}Bi_{0.58}. The core structure 404 may have a composition given by SnₓAg_{y}Cu_{z}, wherein x is a first weight fraction that has a value in a range from approximately 0.952 to approximately 0.965, y is a second weight fraction that has a value in a range from approximately 0.03 to approximately 0.04, and z is a third weight fraction that has a value in a range from approximately 0.005 to approximately 0.008. The first curve 602 corresponds to a shell structure 406 having a thickness 410 of approximately 15 microns, the second curve 604 corresponds to a shell structure 406 having a thickness 410 of approximately 20 microns, and the third curve 606 corresponds to a shell structure 406 having a thickness 410 of approximately 30 microns. Each of the first curve 602, the second curve 604, and the third curve 606 includes three data points corresponding to core structures 404 having diameters 408 (e.g., see FIG. 4A) of 300 microns, 420 microns, and 570 microns, respectively. The above-described compositions are provided as examples, but are not intended to be limiting. Other embodiments may include various other compositions.

Thus, as shown by the first curve 602, for a shell structure 406 having a thickness of 15 microns, the bismuth concentration (i.e., wight fraction of bismuth) varies as 7.8%, 5.8% and 4.3% for the three diameters 408 (300 microns, 420 microns, and 570 microns) of the core structure 404. Similarly, as shown by the second curve 604, for a shell structure 406 having a thickness of 20 microns, the bismuth concentration varies as 10.2%, 7.5% and 5.7% for the three diameters 408 of the core structure 404. Lastly, as shown by the third curve 606, for a shell structure 406 having a thickness of 30 microns, the bismuth concentration varies as 14.4%, 10.8% and 8.3% for the three diameters 408 of the core structure 404. In general, the reflowed bonding material 414 may include a weight fraction of bismuth that is in a range from approximately 4% to approximately 15%. These results suggest that the material properties of the reflowed bonding material 414 (e.g., see FIG. 4C) may be tuned by controlling the concentration of bismuth for various sizes of the core structure 404 that may be appropriate for various applications (i.e., for bonding structures having various sized bonding pads).

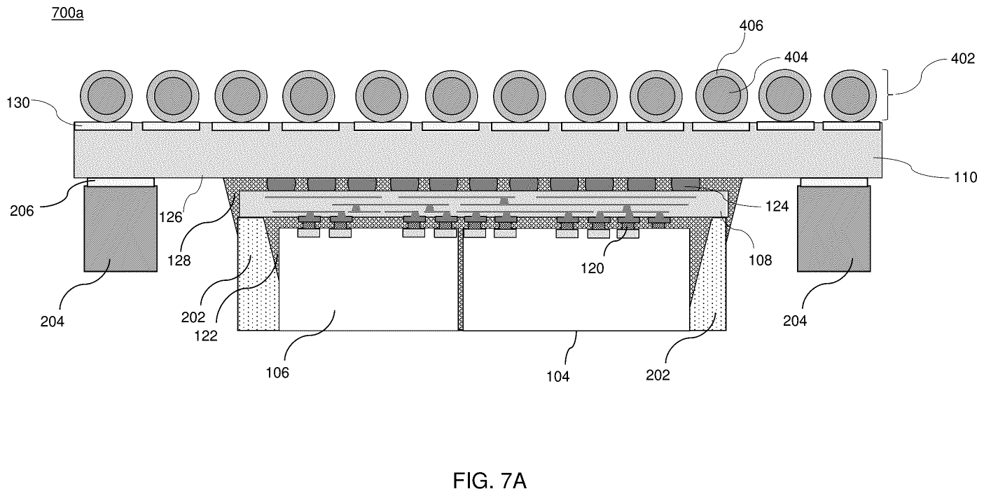

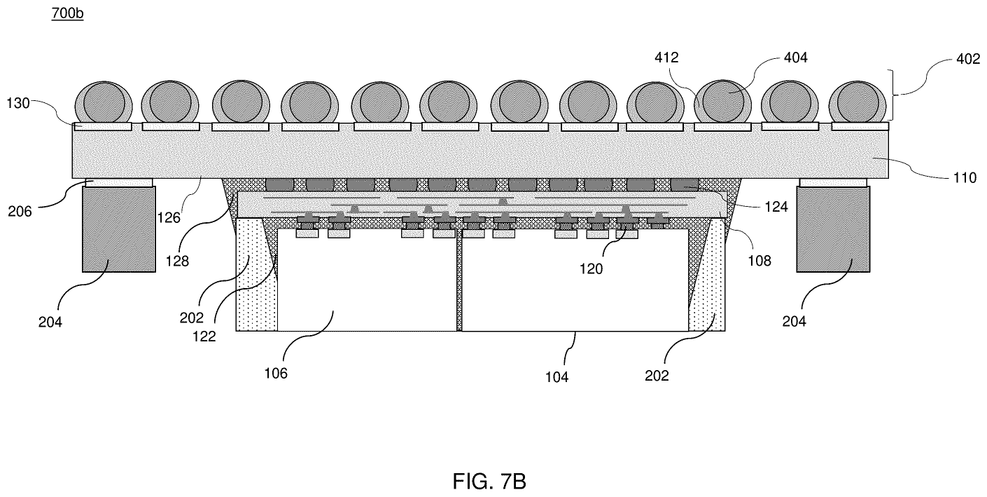

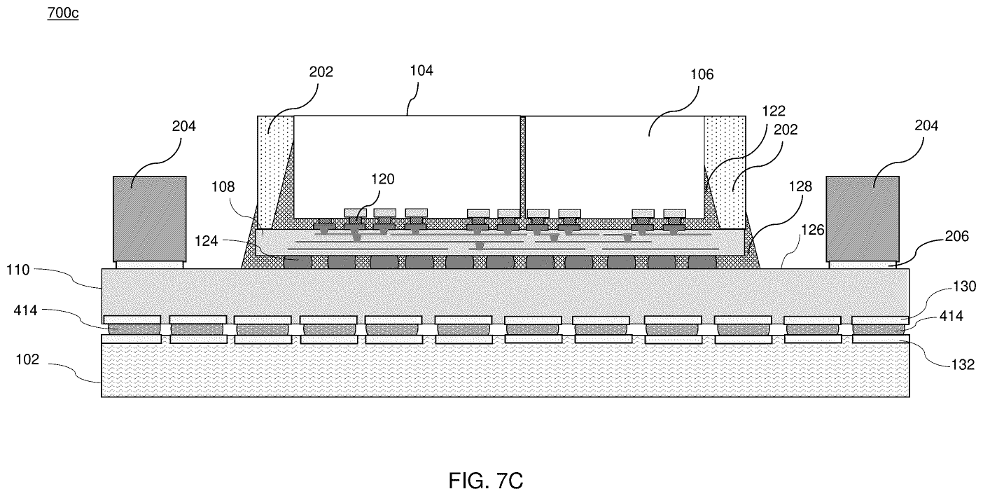

FIG. 7A is a vertical cross-sectional view of an intermediate structure 700a that may be used to form a semiconductor package, and FIG. 7B is a vertical cross-sectional view of a further intermediate structure 700b that may be used to form the semiconductor package, according to various embodiments. The intermediate structure 700a illustrates placement of composite materials 402 prior to a first reflow process and the intermediate structure 700b shows a configuration of the structure after the first reflow process.

The intermediate structure 700a and the intermediate structure 700b may include components similar to those of the semiconductor package 200, described above with reference to FIGS. 2A to 3C. In this regard, the intermediate structure 700a and the intermediate structure 700b may include a first semiconductor die 104 and a second semiconductor die 106 that may be mounted to an interposer 108. A plurality of metal bumps 120, such as microbumps, may electrically connect conductive bonding pads on the bottom surfaces of the first semiconductor dies 104 and second semiconductor dies 106 to the conductive bonding pads on the upper surface of the interposer 108. The interposer 108 may further be mounted to the package substrate 110. A plurality of metal bumps 124, such as C4 solder bumps, may electrically connect conductive bonding pads (not shown) on the bottom surface of the interposer 108 to the conductive bonding pads on the upper surface 126 of the package substrate 110.

A first underfill material portion 122 may be formed between the first semiconductor die 104 and the interposer 108 and between the second semiconductor die 106 and the interposer 108, and a multi-die EMC frame 202 may be formed around the first semiconductor die 104 and the second semiconductor die 106. A second underfill material portion 128 may be formed between the interposer 108 and the package substrate 110. The intermediate structure 700a and the intermediate structure 700b may further include a first reinforcement structure 204. The first reinforcement structure 204 may be attached to the package substrate 110 with an adhesive 206 and may be formed of a metal, an insulator, a semiconductor, a ceramic, etc.

A plurality of composite materials 402 may be placed over the conductive bonding pads 130 of the package substrate 110 prior to performing a first reflow process. As described above (e.g., see FIGS. 4A and 4B), a first reflow process may be performed to melt the first material of the shell structure 406, of the composite materials 402, to thereby form a reflowed second material 412, as shown in FIGS. 4B and 7B. In this regard, the first reflow process may cause the reflowed second material 412 to adhere to the conductive bonding pads 130 as shown, for example, in FIG. 7B. Following the first reflow process, the package substrate 110 may be cooled causing the reflowed second material 412 to re-solidify and to thereby attach the composite material 402 to the conductive bonding pads 130, as shown in FIG. 7B.

As described above, the first material of the core structure 404 may include a tin-silver-copper alloy having a composition given by SnₓAg_{y}Cu_{z}, wherein x is a first weight fraction that has a value in a range from approximately 0.952 to approximately 0.965, y is a second weight fraction that has a value in a range from approximately 0.03 to approximately 0.04, and z is a third weight fraction that has a value in a range from approximately 0.005 to approximately 0.008. For example, the first material of the core structure 404 may have a composition that may be Sn_{0.955}Ag_{0.04}Cu_{0.005}, Sn_{0.965}Ag_{0.030}Cu_{0.005}, Sn_{0.985}Sn_{0.01}Cu_{0.005}, etc. Also, as described above, the second material of the shell structure 406 may have a composition that is given by SnₓBi_{y}, where x is a first weight fraction having a value in a range from 0.42 to approximately 0.6 and y is as second weight fraction having a value in a range from approximately 0.4 to approximately 0.58, and in some embodiments the composition may be given by approximately Sn_{0.42}Bi_{0.58}. The above-described compositions are provided as examples, but are not intended to be limiting. Other embodiments may include various other compositions.

The first reflow process may be performed at a temperature that is in a first range from approximately 170° C. to approximately 180° C. to thereby melt the second material of the shell structure 406 without melting the first material of the core structure 404. In this regard, melting the second material of the shell structure 406 causes the formation of the reflowed second material 412 as shown, for example, in FIGS. 4B and 7B.

FIG. 7C is a vertical cross-sectional view of a semiconductor package 700c, according to various embodiments. The semiconductor package 700c may be formed by bonding the intermediate structure 700b of FIG. 7B to a support substrate 102. In this regard, the intermediate structure 700b of FIG. 7B may be aligned relative to the support substrate 102 such that the conductive bonding pads 130 of the package substrate 110 may be located over corresponding bonding pads (e.g., conductive bonding pads 132) on the support substrate 102. In this way, the reflowed second material 412 of the composite material 402 (e.g., see FIGS. 4B and 7B) may be placed in contact with the conductive bonding pad 132 of the support substrate 102. A second reflow process may then be performed to melt both the first material of the core structure 404 and the reflowed second material 412. For example, the second reflow process may be performed at a temperature that is in a second range from approximately 235° C. to approximately 245° C. Upon performing the second reflow process, the reflowed bonding material 414 may be formed as an alloy of the first and second materials, as described in greater detail (e.g., with reference to FIG. 4C) above.

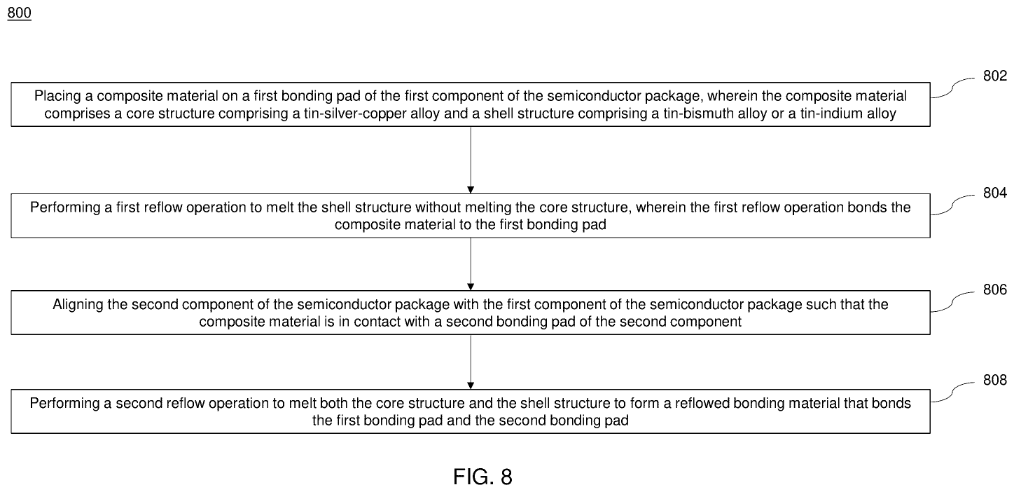

FIG. 8 is a flowchart illustrating operations of a method 800 of bonding a first component of a semiconductor package to a second component of the semiconductor package. In operation 802, the method 800 may include placing a composite material 402 on a first bonding pad 130 of the first component of the semiconductor package (e.g., on the package substrate 110). The composite material 402 may include a core structure 404 including a tin-silver-copper alloy and a shell structure 406 including a tin-bismuth alloy or a tin-indium alloy. In operation 804, the method 800 may further include performing a first reflow process to melt the shell structure 406 (e.g., to form a reflowed second material 412) without melting the core structure 404. As such, the first reflow process may bond the composite material 402 to the first bonding pad 130.

In operation 806, the method 800 may include aligning the second component of the semiconductor package (e.g., the support substrate 102) with the first component of the semiconductor package (e.g., on the package substrate 110) such that the composite material 402 is in contact with a second bonding pad 132 of the second component. In operation 808, the method 800 may further include performing a second reflow process to melt both the core structure 404 and the shell structure 406 (e.g., to melt the reflowed second material 412) to form a reflowed bonding material 414 that bonds the first bonding pad 130 and the second bonding pad 132.

The method 800 may further include performing the first reflow process at a temperature that is in a first range from approximately 170° C. to approximately 180° C., and performing the second reflow operation at a temperature that is in a second range from approximately 235° C. to approximately 245° C. The method 800 may further include forming the shell structure 406 to have a composition given by SnₓIn_{y}, where x is a first weight fraction having a value in a range from approximately 0.75 to approximately 0.85 and y is a second weight fraction having a value in a range from approximately 0.15 to approximately 0.25. The method 800 may further include forming the shell structure 406 to have a composition given by SnₓBi_{y}, wherein x is a first weight fraction having a value in a range from 0.42 to approximately 0.6 and y is as second weight fraction having a value in a range from approximately 0.4 to approximately 0.58. The above-described compositions are provided as examples. Other embodiments may include various other compositions.

Referring to all drawings and according to various embodiments of the present disclosure, a composite material 402 for semiconductor package mount applications is provided. The composite material 402 may include a first component including a tin-silver-copper alloy (e.g., a core structure 404 before performing a reflow operation) and a second component including a tin-bismuth alloy or a tin-indium alloy (e.g., a shell structure 406 before performing a reflow operation). After performing a reflow process (e.g., a first reflow process and a second reflow process), the composite material 402 may form a reflowed bonding material 414 having a room temperature tensile strength in a range from approximately 80 MPa to approximately 100 MPa. In some embodiments reflowed bonding material 414 may include a weight fraction of bismuth that is in a range from approximately 4% to approximately 15% (e.g., see FIG. 6 and related description). The reflowed bonding material 414 may include an alloy that is solid solution strengthened by a presence of bismuth or indium that is dissolved within the reflowed bonding material. In general, the bismuth or indium may have a non-uniform spatial distribution. The reflowed bonding material 414 may include a solid solution phase that includes a minor component of bismuth dissolved within a major component of tin (e.g., see FIG. 5 and related description). The reflowed bonding material 414 may include intermetallic compounds formed as precipitates. For example, the precipitates may include one or more of Ag₃Sn and Cu₆Sn₅.

The second component (e.g., of the shell structure 406) may include a tin-bismuth alloy having a composition given by SnₓBi_{y}, where x is a first weight fraction having a value in a range from 0.42 to approximately 0.6 and y is as second weight fraction having a value in a range from approximately 0.4 to approximately 0.58. In an example embodiment, the second material may include a tin-bismuth alloy having a composition that is approximately Sn_{0.42}Bi_{0.58}. In a further embodiment, the second material may include a tin-indium alloy having a composition SnₓIn_{y}, where x is a first weight fraction having a value in a range from approximately 0.75 to approximately 0.85 and y is a second weight fraction having a value in a range from approximately 0.15 to approximately 0.25. The second component (e.g., of the shell structure 406) may have a composition that approximately corresponds to a eutectic point of a tin-bismuth phase diagram (e.g., see FIG. 5 and related description). The above-described compositions are provided as examples. Other embodiments may include various other compositions.

In various embodiments, the composite material 402 may become partially melted when subjected to a first reflow operation at a first reflow temperature that is in an a range from approximately 130° C. to approximately 150° C. (e.g., see FIG. 4B and related description, above). Further, the composite material 402 may become fully melted when subjected to a second reflow operation at a second reflow temperature that is in an a range from approximately 210° C. to approximately 230° C. (e.g., see FIG. 4C and related description, above).

In a further embodiment, a composite material 402 for semiconductor package mount applications is provided. The composite material 402 may include a tin-silver-copper-bismuth alloy or a tin-silver-copper-indium alloy having a non-uniform spatial distribution of bismuth (e.g., the reflowed bonding material 414 generated by performing a reflow operation on a core structure 404 including a tin-silver-copper alloy, and a shell structure 406 including a tin-bismuth alloy or a tin-indium alloy). The reflowed bonding material 414 may have a room temperature tensile strength in a range from approximately 80 MPa to approximately 100 MPa when subjected to a reflow process (e.g., when subjected to a first reflow process at a first temperature and a second reflow process at a second temperature). The reflowed bonding material 414 may include a weight fraction of bismuth that is in a range from approximately 4% to approximately 15% (e.g., see FIG. 6 and related description). Further, a concentration of bismuth may have a radially varying spatial distribution. The reflowed bonding material 414 may include intermetallic compounds formed as precipitates including one or more of Ag₃Sn and Cu₆Sn₅. (e.g., see FIG. 6 and related description). The reflowed bonding material 414 may include an alloy that is solid solution strengthened by a presence of bismuth or indium that is dissolved within the reflowed bonding material. In certain embodiments, the bismuth or indium may have a greater concentration near a surface of the reflowed bonding material relative to a concentration in an interior of the reflowed bonding material. The reflowed bonding material 414 may include a solid solution phase that includes a minor component of bismuth dissolved within a major component of tin (e.g., see FIG. 5 and related description). In other embodiments, the reflowed bonding material may include a tin-bismuth eutectic phase having a first concentration of the tin-bismuth eutectic phase that is located near a surface of the reflowed bonding material is greater than a second concentration of the tin-bismuth eutectic phase that is located in an interior of the reflowed bonding material. The above-described compositions are provided as examples. Other embodiments may include various other compositions.

The disclosed embodiments may provide advantages over existing semiconductor package mount applications by providing a composite material having a core structure and a shell structure, such that the shell structure may have a lower liquidus point than the core structure. As such, a first reflow process used to attach the composite material to a first component may be performed at a lower temperature than a second reflow process used to attach the composite material to a second component to thereby bond the first and second components to one another. Thermal stresses and corresponding degradation and damage, caused by such thermal stresses, may be reduced by using a first reflow process that has a lower reflow temperature than that of a second reflow process. As a further advantage, the composite material, once having been subjected to the first reflow process and the second reflow process, may have a greater tensile strength than existing materials used for semiconductor package mount applications.

As described above, the composite material may be subjected to a first reflow process and to a second reflow process. In embodiments in which the first reflow process may be performed at a relatively low temperature (e.g., below 190° C.), the material may have a heterogeneous structure resulting from the first reflow process as shown, for example, in FIG. 4B. In the above-described embodiments, the first reflow operation may be performed at a relatively low temperature and the second reflow operation may be performed at a higher temperature (e.g., over 217° C.). The use of a higher temperature second reflow operation may be advantageous in certain embodiments because the resulting reflowed bonding material 414 may have increased mechanical strength due to alloying of material from the core structure 404 with material from the shell structure 406. However, the second reflow operation need not be performed at the higher temperature in all embodiments. For example, in certain temperature sensitive embodiments, both the first reflow operation and the second reflow operations may be performed at the lower temperature. In such applications, the reflowed second material 412 formed from the material of the shell structure 406 may be sufficient for bonding applications. As such, the composite material would have a heterogeneous spatial composition distribution having a Sn—Bi composition in an outer phase and a Sn—Ag—Cu inner phase.

The final composition need not be spatially uniform even in embodiments in which a high temperature second reflow process is used. For example, the reflowed bonding material 414 (e.g., see FIG. 4C) may have a composition that varies with radial position. In this regard, a distribution of Bi may have a radially varying spatial distribution that may be detected using certain testing procedures, such as energy-dispersive x-ray spectroscopy (EDS). For example, certain embodiments may have a radial distribution of Bi that may increase with distance from the center of the reflowed bonding material 414 to the surface. For certain compositions, the reflowed bonding material 414 may include a Sn—Bi eutectic phase (e.g., including precipitates) that may be detected, for example, using scanning electron microscopy (SEM). The amount of the Sn—Bi eutectic phase may be a function of a thickness of the shell structure 406. The presence of the Sn—Bi eutectic phase may also have a radial distribution having a larger concentration near the surface of the reflowed bonding material 414.

The foregoing outlines features of several embodiments so that those skilled in the art may better understand the aspects of the present disclosure. Those skilled in the art should appreciate that they may readily use the present disclosure as a basis for designing or modifying other processes and structures for achieving the same purposes and/or the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of bonding a first component of a semiconductor package to a second component of the semiconductor package, comprising;
placing a composite material on a first bonding pad of the first component of the semiconductor package, wherein the composite material comprises a core structure comprising a first tin-containing alloy and a shell structure comprising a second tin-containing alloy having a different composition than the first tin-containing alloy;
performing a first reflow process to melt the shell structure without melting the core structure, wherein the first reflow process bonds the composite material to the first bonding pad;
aligning the second component of the semiconductor package with the first component of the semiconductor package such that the composite material is in contact with a second bonding pad of the second component; and
performing a second reflow process to melt both the core structure and the shell structure to form a reflowed bonding material that bonds the first bonding pad and the second bonding pad.

2. The method of claim 1, wherein the first tin-containing alloy comprises a tin-silver-copper alloy and the second tin-containing alloy comprises a tin-indium alloy.

3. The method of claim 1, further comprising:
performing the first reflow process at a first temperature that is in a first range from approximately 170° C. to approximately 180° C.; and
performing the second reflow process at a second temperature that is in a second range from approximately 235° C. to approximately 245° C.

4. The method of claim 1, further comprising:
forming the shell structure to comprise a composition given by SnₓIn_{y},
wherein x is a first weight fraction having a value in a range from approximately 0.75 to approximately 0.85 and y is a second weight fraction having a value in a range from approximately 0.15 to approximately 0.25.

5. The method of claim 1, wherein the first component of the semiconductor package comprises a package substrate comprising a first side and a second side, at least one semiconductor die is mounted over the first side of the package substrate, and the first bonding pad is located on the second side of the package substrate.

6. The method of claim 5, wherein the semiconductor package further comprises an interposer mounted over the first side of the package substrate and a plurality of semiconductor dies mounted to the interposer.

7. The method of claim 6, wherein the semiconductor package further comprises a reinforcement structure mounted to the first side of the package substrate and laterally surrounding the interposer.

8. The method of claim 5, wherein the second component of the semiconductor package comprises a printed circuit board (PCB).

9. The method of claim 1, wherein the reflowed bonding material comprises a room temperature tensile strength in a range from approximately 80 MPa to approximately 100 MPa.

10. The composite material of claim 2, wherein the second component is a tin-indium alloy comprising a composition SnₓIn_{y}, where x is a first weight fraction having a value in a range from approximately 0.75 to approximately 0.85 and y is a second weight fraction having a value in a range from approximately 0.15 to approximately 0.25.

11. The method of claim 1, wherein the reflowed bonding material comprises intermetallic compounds formed as precipitates.

12. The method of claim 11, wherein the precipitates comprise one or more of Ag₃Sn and Cu₆Sn₅.

13. The method of claim 1, wherein the composite material becomes partially melted when subjected to a first reflow operation at a first reflow temperature that is in an a range from approximately 130° C. to approximately 150° C., and
wherein the composite material becomes fully melted when subjected to a second reflow operation at a second reflow temperature that is in an a range from approximately 210° C. to approximately 230° C.

14. A method of fabricating a semiconductor device, comprising:
mounting a semiconductor die over a first side of a substrate;
providing a plurality of bonding structures contacting respective first bonding pads located on a second side of the substrate, wherein each of the bonding structures comprises a core structure comprising a tin-silver-copper alloy and a shell structure comprising a tin-indium alloy;
performing a first reflow process at a first temperature to bond the bonding structures to the first bonding pads;
aligning the substrate over a support having a plurality of second bonding pads such that each of the bonding structures contacts a corresponding second bonding pad; and
performing a second reflow process at a second temperature that is higher than the first temperature to form a reflowed bonding material that bonds the bonding structures to second bonding pads to bond the substrate to the support.

15. The method of claim 14, wherein the first temperature is between 170° C. and 180° C., and the second temperature is between 235° C. and 245° C.

16. The method of claim 14, wherein the reflowed bonding material comprises an alloy that is solid solution strengthened by a presence of indium that is dissolved within the reflowed bonding material, and
wherein the indium has a greater concentration near a surface of the reflowed bonding material relative to a concentration in an interior of the reflowed bonding material.

17. The method of claim 14, wherein each of the core structures of the bonding structures has a diameter between 100 μm and 600 μm and each of the shell structures of the bonding structures has a thickness that is between 15 μm and 40 μm.

18. The method of claim 14, wherein mounting the semiconductor die over a first surface of a substrate comprises:
mounting a plurality of semiconductor dies to a first side of an interposer via a plurality of metal bump bonding structures;
forming a first underfill material portion between the plurality of semiconductor dies and the first surface of the interposer and laterally surrounding the metal bump bonding structures;
forming a molding portion laterally surrounding the plurality of semiconductor dies;
mounting the interposer to the first side of the substrate via a plurality of solder material portions between a second side of the interposer and the first side of the substrate; and
forming a second underfill material portion between the second side of the interposer and the first side of the substrate and laterally surrounding the plurality of solder material portions.

19. A method of bonding a semiconductor device structure to a support, comprising;
placing a composite material on a first bonding pad of the semiconductor device structure, wherein the composite material comprises a core structure comprising a tin-silver-copper alloy and a shell structure comprising a tin-indium alloy;
performing a first reflow process to melt the shell structure without melting the core structure, wherein the first reflow process bonds the composite material to the first bonding pad; and
performing a second reflow process to melt both the core structure and the shell structure to form a reflowed bonding material that bonds the semiconductor device structure to the support.

20. The method of claim 19, wherein the shell structure to comprises a composition given by SnₓIn_{y}, wherein x is a first weight fraction having a value in a range from approximately 0.75 to approximately 0.85 and y is a second weight fraction having a value in a range from approximately 0.15 to approximately 0.25.
